(19) United States
(12) Patent Application Publication
(10) Pub. No.: US 2025/0208223 A1
(43) Pub. Date: Jun. 26, 2025

(54) APPARATUS FOR CALCULATING INTEGRATED STATE OF CHARGE OF ECO-FRIENDLY VEHICLE EQUIPPED WITH MAIN BATTERY AND AUXILIARY BATTERY, AND ECO-FRIENLY VEHICLE INCLUDING SAME

(71) Applicants: Hyundai Motor Company, Seoul (KR); Kia Corporation, Seoul (KR)

(72) Inventors: Soo Yang Jin, Hwaseong-si (KR); Hyo Seung Jeon, Hwaseong-si (KR)

(21) Appl. No.: 18/760,531

(22) Filed: Jul. 1, 2024

(30) Foreign Application Priority Data
Dec. 22, 2023 (KR) 10-2023-0190109

(51) Int. Cl. G01R 31/387; B60L 58/13; B60L 58/22; G01R 31/36; G01R 31/396; H02J 7/00

(52) U.S. Cl. CPC G01R 31/387; B60L 58/13; B60L 58/22; G01R 31/3646; G01R 31/396; H02J 7/0048; B60L 2210/30

(57) ABSTRACT

An embodiment apparatus configured to calculate an integrated state-of-charge (SOC) for a vehicle equipped with a main battery and an auxiliary battery includes one or more processors and a storage device storing a program to be executed by the one or more processors, the program including instructions to receive a SOC of the main battery, receive a SOC of the auxiliary battery, and calculate an integrated SOC of the main battery and the auxiliary battery, based on the SOC of the main battery and the SOC for the auxiliary battery.

### CROSS-REFERENCE TO RELATED APPLICATIONS

This application claims the benefit of Korean Patent Application No. 10-2023-0190109, filed on Dec. 22, 2023, which application is hereby incorporated herein by reference in its entirety.

### TECHNICAL FIELD

The present disclosure relates to an apparatus for calculating an integrated state-of-charge (SOC) for an eco-friendly vehicle equipped with a main battery and an auxiliary battery, and an eco-friendly vehicle including the same.

### BACKGROUND

Eco-friendly vehicles refer to low-carbon, high-fuel-efficiency vehicles that emit fewer existing air pollutants and greenhouse gases and have excellent fuel efficiency, such as use of new electric power sources such as batteries, fuel cells, or the like, ultra-high-efficiency new combustion technologies, or the like.

These eco-friendly vehicles may be largely divided into an electric power-based vehicle and an engine-based vehicle, and in particular, the electric power-based vehicle may be called an xEV. The xEV may include a hybrid electric vehicle (HEV), a plug-in hybrid vehicle (PHEV), an electric vehicle (EV), a fuel cell electric vehicle (FCEV), and the like.

The xEV may include a main battery for supplying driving electric power to a driving motor and may include separately a main battery management unit for managing state-of-charge (SOC) of the main battery.

Recently, research and development are underway on the xEV, which may include further an auxiliary battery and an auxiliary battery management unit for supporting the main battery.

However, the main battery management unit and the auxiliary battery management unit may operate separately and may output the SOC of the main battery and the SOC of the auxiliary battery independently, but there is no disclosed apparatus for calculating both thereof in an integrated manner.

### SUMMARY

An embodiment of the present disclosure provides an apparatus for calculating an integrated state-of-charge (SOC) for an eco-friendly vehicle equipped with a main battery and an auxiliary battery, and an eco-friendly vehicle including the same, which may be used to calculate the integrated SOC of the main battery and the auxiliary battery in the eco-friendly vehicle equipped with the main battery and the auxiliary battery, to provide accurate remaining SOC and driving distance information to a user.

According to an embodiment of the present disclosure, an apparatus for calculating an integrated state-of-charge (SOC) for an eco-friendly vehicle equipped with a main battery and an auxiliary battery includes at least one processor and a storage medium storing a computer-readable instruction, wherein the computer-readable instruction, when the computer-readable instruction is executed by the at least one processor, is configured to, by the at least one processor, receive the SOC of the main battery, receive the SOC for the auxiliary battery, and calculate the integrated SOC of the main battery and the auxiliary battery, based on the SOC of the main battery and the SOC for the auxiliary battery.

According to another embodiment of the present disclosure, an eco-friendly vehicle includes a main battery, an auxiliary battery, a charging and driving unit charging the main battery with electric power stored in the auxiliary battery or driving a motor using electric power stored in at least one of the main battery or the auxiliary battery to maintain a state-of-charge (SOC) of the main battery at a minimum SOC, and an apparatus for calculating an integrated SOC of the main battery and the auxiliary battery, based on the SOC of the main battery and an SOC for the auxiliary battery.

### BRIEF DESCRIPTION OF THE DRAWINGS

The above and other aspects, features, and advantages of embodiments of the present disclosure will be more clearly understood from the following detailed description, taken in conjunction with the accompanying drawings, in which:

FIG. 1 is a view illustrating an eco-friendly vehicle including an apparatus for calculating an integrated state-of-charge (SOC) for an eco-friendly vehicle equipped with a main battery and an auxiliary battery, according to an embodiment of the present disclosure.

FIG. 2 is a circuit diagram of a motor system according to an embodiment of the present disclosure.

FIGS. 3A and 3B are waveform diagrams of phase current of a motor and current of an auxiliary battery when a charging mode is performed during driving, according to an embodiment of the present disclosure.

FIG. 4 is a flowchart illustrating a method for calculating an integrated state-of-charge (SOC) for an eco-friendly vehicle equipped with a main battery and an auxiliary battery, according to an embodiment of the present disclosure.

FIG. 5 is a block diagram of a computing device that may fully or partially implement an apparatus for calculating an integrated state-of-charge (SOC) for an eco-friendly vehicle, equipped with a main battery and an auxiliary battery, according to an embodiment of the present disclosure.

### DETAILED DESCRIPTION OF ILLUSTRATIVE EMBODIMENTS

Hereinafter, specific embodiments of the present disclosure will be described with reference to the accompanying drawings. The following detailed description is provided to aid in a comprehensive understanding of a method, a device, and/or a system described in the present specification. However, the detailed description is for illustrative purposes only, and the present disclosure is not limited thereto.

In describing the embodiments of the present disclosure, when it is determined that a detailed description of a known technology related to the present disclosure may unnecessarily obscure the gist of the present disclosure, a detailed description thereof will be omitted. In addition, terms to be described later are terms defined in consideration of functions in the present disclosure, which may vary depending on intention or custom of a user or operator. Therefore, the definition of these terms should be made based on the contents throughout the present specification. The terminology used herein is for the purpose of describing particular embodiments only and is not to be limiting of the embodiments. As used herein, the singular forms are intended to include the plural forms as well, unless the context clearly indicates otherwise. As used herein, the terms “comprise,” “include,” “have,” or the like, when used in this specification, specify the presence of stated features, integers, steps, operations, elements, components, or a combination thereof, but they do not preclude the presence or addition of one or more other features, integers, steps, operations, elements, components, and/or groups thereof.

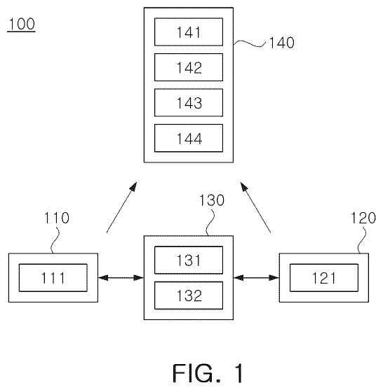

FIG. 1 is a view illustrating an eco-friendly vehicle including an apparatus for calculating an integrated state-of-charge (SOC) for an eco-friendly vehicle equipped with a main battery and an auxiliary battery, according to an embodiment of the present disclosure. An eco-friendly vehicle 100 may include a main battery 110, an auxiliary battery 120, a charging and driving unit 130, and an apparatus 140 for calculating an integrated state-of-charge (SOC).

In embodiments of the present disclosure, the eco-friendly vehicle may refer to an electric power-based vehicle, and may be an xEV including a hybrid electric vehicle (HEV), a plug-in hybrid vehicle (PHEV), an electric vehicle (EV), a fuel cell electric vehicle (FCEV), and the like.

In addition, the apparatus 140 may include a processor (e.g., a computer, a microprocessor, a CPU, an ASIC, a logic circuit, or the like) and a memory storing software instructions that provide functions of a control unit 142, described below, when executed by the processor. In this case, the processor and the memory may be implemented as separate semiconductor circuits. Alternatively, the processor and the memory may be implemented as a single integrated semiconductor circuit. The processor may be provided as at least one processor.

Specifically, the main battery 110 may be a battery that provides electric power for driving a motor. The state of charge (SOC) of the main battery 110 may be calculated in real time by a main battery management unit (MBMU) 111 provided in the main battery 110 and the calculated SOC may be transmitted to the apparatus 140.

The auxiliary battery 120 may be a battery that provides electric power for charging the main battery 110 such that the SOC of the main battery 110 maintains a minimum SOC or for driving the motor. The SOC for the auxiliary battery 120 may be calculated in real time by an auxiliary battery management unit (ABMU) 121 provided in the auxiliary battery 120, and the calculated SOC may be transmitted to the apparatus 140.

The maximum capacity of the auxiliary battery 120 may be lower than the maximum capacity of the main battery 110, and the auxiliary battery 120 may be a different type of battery from the main battery 110.

In addition, the main battery 110 and the auxiliary battery 120, described above, may be high-voltage batteries for driving the motor, may have a rated voltage of 400V to 800V, and may be different from a battery that may be used to supply operating electric power of 12V to 48V to an electrical load of the eco-friendly vehicle 100.

The charging and driving unit 130 may charge the main battery 110 with electric power stored in the auxiliary battery 120 such that the SOC of the main battery 110 maintains a minimum SOC, or it may drive the motor using electric power stored in at least one of the main battery 110 or the auxiliary battery 120. The minimum SOC may be appropriately selected according to a need of those skilled in the art in consideration of performance of the main battery 110, and it should be noted that embodiments of the present disclosure are not limited to a specific value.

The charging and driving unit 130 may include an AC/DC converter 131 for charging the main battery 110 and the auxiliary battery 120 with commercial AC electric power and a motor system 132 for controlling the motor based on at least one of the main battery 110 and the auxiliary battery 120. In addition, the motor system 132 may increase voltage of the auxiliary battery 120 during driving to charge the main battery 110, or it may decrease voltage of the main battery 110 to charge the auxiliary battery 120.

Hereinafter, the motor system 132 will be described in more detail.

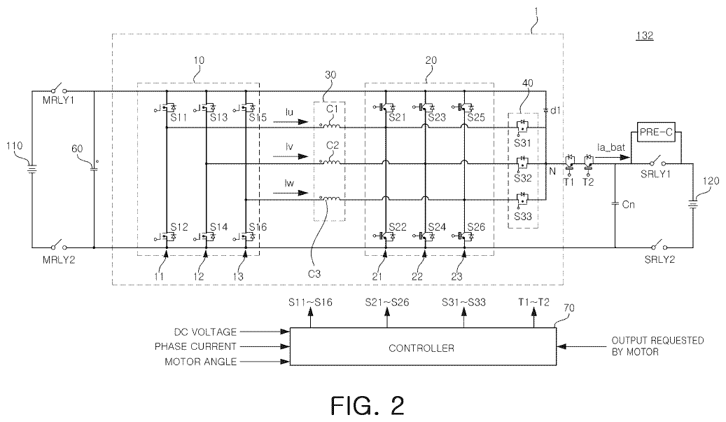

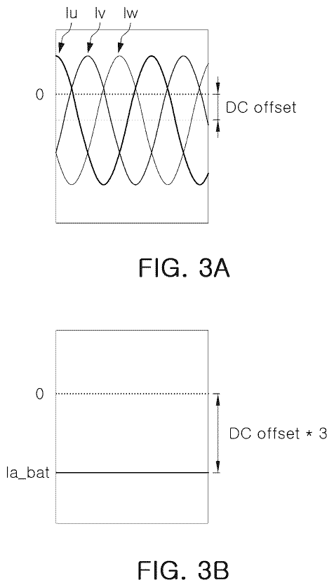

FIG. 2 is a circuit diagram of a motor system according to an embodiment of the present disclosure, and FIGS. 3A and 3B are waveform diagrams of phase current of a motor and current of an auxiliary battery when a charging mode is performed during driving, according to an embodiment of the present disclosure.

As illustrated in FIG. 2, a motor system 132 may include a direct current capacitor (or a DC-link capacitor) 60, a controller 70, and a driving system 1. In addition, the driving system 1 may include a dual inverter (10 and 20), a motor 30 having a plurality of windings C1, C2, and C3 corresponding to a plurality of phases, and a mode switching unit 40. Hereinafter, among a first inverter 10 and a second inverter 20, a first driving mode will be referred to as a mode (closed end winding (CEW)) controlling driving of the motor 30 through the first inverter 10, and a second driving mode will be referred to as a mode (open end winding (OEW)) controlling driving of the motor 30 through the first inverter 10 and the second inverter 20.

Hereinafter, an operation method by which the controller 70 controls performance of a motor drive mode including the CEW mode and the OEW mode and performance of a charging mode during driving will be described.

When the CEW mode is performed, the controller 70 may be controlled to turn on a changeover switch (S31, S32, and S33) to form a neutral point of the motor 30 at an internal node N, turn off a charging switch (T1 and T2) such that a voltage increasing and charging path connected to the main battery 110 through the driving system 1 in the auxiliary battery 120 is blocked, and drive the motor 30 through the first inverter 10 among the first and second inverters 10 and 20.

When the OEW mode is performed, the controller 70 may be controlled to turn off the changeover switch (S31, S32, and S33) not to form the neutral point of the motor 30 at the internal node N, turn off the charging switch (T1 and T2) such that the voltage increasing and charging path is blocked, and drive the motor 30 through the first and second inverters 10 and 20.

When the CEW mode or OEW mode is performed, the controller 70 may control space vector pulse width modulation (SVPWM) without direct current (DC) offset for respective phase currents Iu, Iv, and Iw of the motor 30.

The controller 70 may set a value of a zero-phase current command for the direct current (DC) offset to ‘o’. In this case, the SVPWM control may refer to a method of synthesizing a reference voltage vector using two effective voltage vectors adjacent to the reference voltage vector, together with a zero-voltage vector, in a complex space.

The controller 70 may convert the CEW mode into the charging mode, during driving, based on a predetermined command regarding performance of the charging mode.

When the charging mode is performed during driving, the controller 70 may be controlled to turn on the changeover switch (S31, S32, and S33) to form the neutral point of the motor 30 at the internal node N, turn on the charging switch (T1 and T2) to form the voltage increasing and charging path connected to the main battery 110 through the driving system 1 in the auxiliary battery 120, and drive the motor 30 through the first inverter 10 among the first and second inverters 10 and 20.

In addition, when the charging mode is performed during driving, the controller 70 may apply direct current (DC) offset for each of the phase currents Iu, Iv, and Iw of the motor 30 having a plurality of phases, based on the charging current command for the auxiliary battery 120. More specifically, when the charging mode is performed during driving, the controller 70 may divide the value of the charging current command by the number of phases (e.g., 3) to generate a zero-phase current command for the direct current (DC) offset and may output a plurality of switching signals for pulse width modulation control based on the zero-phase current command.

Referring to FIGS. 3A and 3B, when a charging mode is performed during driving, phase currents Iu, Iv, and Iw of the motor 30 (see, FIG. 3A) and a waveform (see, FIG. 3B) regarding the auxiliary battery 120 are illustrated.

As illustrated in FIG. 3A, the phase currents Iu, Iv, and Iw of the motor may have a direct current (DC) offset, respectively, and may have a 120° phase difference from each other. Additionally, as illustrated in FIG. 3B, charging current Ia_bat may be equal to a sum of the phase currents Iu, Iv, and Iw of the motor and may then have a direct current waveform obtained by multiplying the direct current (DC) offset by the number of phases (e.g., 3).

Therefore, when the controller 70 applies a negative direct current (DC) offset to the phase currents Iu, Iv, and Iw of the motor, respectively, the charging current Ia_bat may be output from the auxiliary battery 120 to the main battery 110, and the driving system 1 may then transfer electric power of the auxiliary battery 120 to the main battery 110. In contrast, when the controller 70 applies a positive direct current (DC) offset to the phase currents Iu, Iv, and Iw of the motor, respectively, the charging current Ia_bat may be output from the main battery 110 to the auxiliary battery 120, and the driving system 1 may then transfer electric power of the main battery 110 to the auxiliary battery 120.

When the charging mode is performed during driving, the controller 70 may output a plurality of switching signals Su, Sv, and Sw for performing preset pulse width modulation control for the first inverter 10, to increase voltage of the auxiliary battery 120 to charge the main battery 110 by the driving system 1, and the controller 70 may control the direct current (DC) offset for each of the phase currents Iu, Iv, and Iw of the motor. In this case, the plurality of switching signals Su, Sv, and Sw may correspond to a first leg 11, a second leg 12, and a third leg 13, respectively. In this embodiment, the preset pulse width modulation control may be set as space vector pulse width modulation (SVPWM) control or remote state pulse width modulation (RSPWM) control. In this case, the RSPWM control may refer to a method of synthesizing a reference voltage vector using three effective voltage vectors having a 120° phase difference from each other in a complex space.

In embodiments of the present disclosure, two inverters 10 and 20 are illustrated, but are only illustrative, and of course, a single inverter may be used.

An apparatus 140 may receive the SOC of the main battery 110, may receive the SOC for the auxiliary battery 120, and may then calculate the integrated SOC of the main battery 110 and the auxiliary battery 120, based on the SOC of the main battery 110 and the SOC for the auxiliary battery 120. The apparatus 140 may operate when an eco-friendly vehicle 100 is parked or stopped.

The apparatus 140 may include a communication unit 141, the control unit 142, a storage unit 143, and an input/output unit 144.

Specifically, the communication unit 141 may receive the SOC of the main battery 110 from the main battery management unit 111, may receive the SOC for the auxiliary battery 120 from the auxiliary battery management unit 121, and may transmit them to the control unit 142.

The control unit 142 may calculate the integrated SOC (ISOC) of the main battery 110 and the auxiliary battery 120, based on the SOC of the main battery 110 and the SOC for the auxiliary battery 120. In this case, the integrated SOC may be calculated according to Equation 1 below, in consideration of the maximum capacity of the main battery 110 and the maximum capacity of the auxiliary battery 120.

$$ISOC = ( SOC\_M \times MC\_M + SOC\_A \times MC\_A ) / ( MC\_M + MC\_A ) \qquad Equation 1$$

In this case, ISOC is the integrated SOC, SOC_M is the SOC of the main battery, MC_M is the maximum capacity of the main battery, SOC_A is the SOC for the auxiliary battery, and MC_A is the maximum capacity of the auxiliary battery.

In this case, the SOC of the main battery 110 may be a SOC for display in which the actual SOC range of the main battery 110, including preset lower and upper limits, may be converted to correspond to a range of 0 to 100.

Additionally, the SOC for the auxiliary battery 120 may be a SOC for display in which an actual SOC range of the auxiliary battery 120, including a preset lower limit and a preset upper limit, is converted to correspond to a range of 0 to 100.

For example, the actual SOC may be designed to be, for example, 5% to 95%, considering a safety margin of the battery, and it may be converted to correspond to a range of 0 to 100 to illustrate the same to a driver.

The control unit 142 may diagnose based on the actual SOC of the main battery 110 and the actual SOC for the auxiliary battery 120 during self-diagnosis.

Additionally, the control unit 142 may display an output limit notification through the input/output unit 144, which will be described later, when at least one of the SOC of the main battery 110 or the SOC for the auxiliary battery 120 is less than a preset reference value. The reference value may be a case in which electric power is not sufficient to drive the motor, and it may be appropriately selected according to the needs of those skilled in the art. Therefore, it should be noted that embodiments of the present disclosure are not limited to specific values.

Lastly, the storage unit 143 may store various programs and data to implement functions performed by the control unit 142 described above.

Finally, when at least one of the SOC of the main battery 110 or the SOC for the auxiliary battery 120 is less than a preset reference value under control of the control unit 142, the input/output unit 144 may display an output limit notification through the input/output unit 144 to be described later.

As described above, according to an embodiment of the present disclosure, an apparatus for calculating an integrated state-of-charge (SOC) for an eco-friendly vehicle equipped with a main battery and an auxiliary battery may be used to calculate the integrated SOC of the main battery and the auxiliary battery, based on a main SOC of the main battery and an auxiliary SOC for the auxiliary battery, to provide accurate remaining SOC and driving distance information to a user.

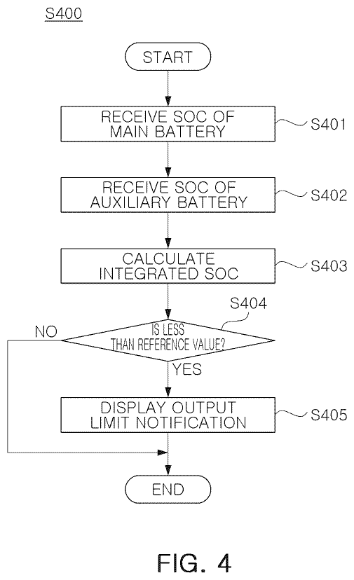

FIG. 4 is a flowchart illustrating a method for calculating an integrated state-of-charge (SOC) for an eco-friendly vehicle equipped with a main battery and an auxiliary battery, according to an embodiment of the present disclosure.

Hereinafter, a method for calculating an integrated state-of-charge (SOC) for an eco-friendly vehicle equipped with a main battery and an auxiliary battery, according to an embodiment of the present disclosure, will be described with reference to FIGS. 1 to 4. However, for simplification of the present disclosure, descriptions overlapping FIG. 1 will be omitted.

Referring to FIGS. 1 to 4, a method (S400) for calculating an integrated state-of-charge (SOC) for an eco-friendly vehicle equipped with the main battery 110 and the auxiliary battery 120, according to an embodiment of the present disclosure, may include receiving the SOC of the main battery 110 and receiving the SOC for the auxiliary battery 120 (S401 and S402).

Thereafter, the apparatus 140 for calculating the integrated SOC may calculate the integrated SOC of the main battery 110 and the auxiliary battery 120, based on the SOC of the main battery 110 and the SOC for the auxiliary battery 120 (S403). In this case, as described above, the integrated SOC may be calculated according to Equation 1 in consideration of the maximum capacity of the main battery 110 and the maximum capacity of the auxiliary battery 120.

In this case, the SOC of the main battery 110 may be a SOC for display in which an actual SOC range of the main battery 110, including a preset lower limit and a preset upper limit, is converted to correspond to a range of 0 to 100.

Additionally, the SOC for the auxiliary battery 120 may be a SOC for display in which an actual SOC range of the auxiliary battery 120, including a preset lower limit and a preset upper limit, is converted to correspond to a range of 0 to 100.

As described above, the apparatus 140 may diagnose based on the actual SOC of the main battery 110 and the actual SOC for the auxiliary battery 120 during self-diagnosis.

Thereafter, the apparatus 140 may determine whether at least one of the SOC of the main battery 110 or the SOC for the auxiliary battery 120 is less than a preset reference value (S404).

As a result of determination in S404, when at least one of the SOC of the main battery 110 or the SOC for the auxiliary battery 120 is less than the preset reference value, the apparatus 140 may display an output limit notification through the input/output unit 144 (S405).

As described above, according to an embodiment of the present disclosure, an apparatus for calculating an integrated state-of-charge (SOC) for an eco-friendly vehicle equipped with a main battery and an auxiliary battery may be used to calculate the integrated SOC of the main battery and the auxiliary battery, based on the main SOC of the main battery and the auxiliary SOC for the auxiliary battery, to provide accurate remaining SOC and driving distance information to a user.

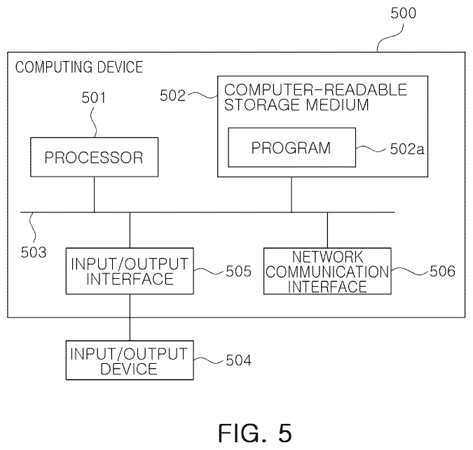

FIG. 5 is a block diagram of a computing device that may fully or partially implement the apparatus 140 for calculating an integrated state-of-charge (SOC) for an eco-friendly vehicle, equipped with a main battery and an auxiliary battery, according to an embodiment of the present disclosure.

As illustrated in FIG. 5, a computing device 500 may include at least one processor 501, a computer-readable storage medium 502, and a communication bus 503.

The processor 501 may enable the computing device 500 to operate according to the above-mentioned embodiments. For example, the processor 501 may execute one or more programs 502a stored in the computer-readable storage medium 502. The one or more programs 502a may include one or more computer-executable instructions, which, when executed by the processor 501, cause the computing device 500 to perform operations according to embodiments.

The computer-readable storage medium 502 may be configured to store a computer-executable instruction or program code, program data, and/or information having other suitable form. The program 502a stored in the computer-readable storage medium 502 may include a set of instructions executable by the processor 501. In an embodiment, the computer-readable storage medium 502 may include a memory (a volatile memory, such as a random access memory, a non-volatile memory, or an appropriate combination thereof), at least one magnetic disk storage device, at least one optical disk storage device, at least one flash memory device, a storage medium accessible by the computing device 500 and storing desired information, or a suitable combination thereof.

The communication bus 503 may interconnect various other components of the computing device 500, including the processor 501 and the computer-readable storage medium 502.

The computing device 500 may also include at least one input/output interface 505 and at least one network communication interface 506, providing an interface for at least one input/output device 504. The input/output interface 505 and the network communication interface 506 may be connected to the communication bus 503. The network may be one of a cellular network, such as global system for mobile communications (GSM), enhanced data rates for GSM evolution (EDGE), general packet radio service (GPRS), code division multiple access (CDMA), time division-CDMA (TD-CDMA), universal mobile telecommunications system (UMTS), long term evolution (LTE), or another cellular network.

The input/output device 504 may be coupled to other components of the computing device 500 through the input/output interface 505. An example input/output device 504 may include, but is not limited to, an input device such as a pointing device (such as a mouse, a trackpad, or the like), a keyboard, a touch input device (such as a touchpad, a touch screen, or the like), a voice or sound input device, various types of sensor devices, and/or various types of imaging devices, and/or an output device such as a display device, a printer, a speaker, and/or a network card. The example input/output device 504 may be included in the computing device 500 as a component constituting the computing device 500, or it may be connected to the computing device 500 as a separate device distinct from the computing device 500.

An embodiment of the present disclosure may include a program for performing methods described in the present specification on a computer and a computer-readable recording medium containing the program. The computer-readable recording medium may include a program instruction, a local data file, a local data structure, or the like, singly or in combination. The medium may be those specifically designed and constructed for the present disclosure, or the medium may be those commonly available in a computer software field. Examples of the computer-readable recording medium may include a magnetic medium such as a hard disk, a floppy disk, or a magnetic tape, an optical recording medium such as a CD-ROM or a DVD, and a hardware device specifically configured to store and perform a program instruction such as a ROM, a RAM, a flash memory, or the like. Examples of the program may include not only a machine language code such as that generated by a compiler, but also a high-level language code that may be executed by a computer using an interpreter or the like.

According to an embodiment of the present disclosure, in an apparatus for calculating an integrated state-of-charge (SOC) for an eco-friendly vehicle equipped with a main battery and an auxiliary battery, the integrated SOC of the main battery and the auxiliary battery in the eco-friendly vehicle equipped with the main battery and the auxiliary battery may be calculated to provide accurate remaining SOC and driving distance information to a user.

While example embodiments have been illustrated and described above, it will be apparent to those skilled in the art that modifications and variations could be made without departing from the scope of the present disclosure as defined by the appended claims.

What is claimed is:

1. An apparatus configured to calculate an integrated state-of-charge (SOC) for a vehicle equipped with a main battery and an auxiliary battery, the apparatus comprising:
one or more processors; and
a storage device storing a program to be executed by the one or more processors, the program including instructions to:
receive a SOC of the main battery;
receive a SOC of the auxiliary battery; and
calculate an integrated SOC of the main battery and the auxiliary battery, based on the SOC of the main battery and the SOC for the auxiliary battery.

2. The apparatus of claim 1, wherein:
the main battery is configured to supply electric power to drive a driving motor of the vehicle; and
the auxiliary battery is configured to supply electric power to charge the main battery such that the SOC of the main battery maintains a minimum SOC or to drive the driving motor.

3. The apparatus of claim 1, wherein a maximum capacity of the auxiliary battery is lower than a maximum capacity of the main battery.

4. The apparatus of claim 1, wherein the auxiliary battery is a different type of battery from the main battery.

5. The apparatus of claim 1, wherein the program further includes instructions to calculate the integrated SOC of the main battery and the auxiliary battery in consideration of a maximum capacity of the main battery and a maximum capacity of the auxiliary battery.

6. The apparatus of claim 5, wherein the program further includes instructions to calculate the integrated SOC according to an equation,
ISOC=(SOC_M×MC_M+SOC_A×MC_A)/(MC_M+MC_A), wherein ISOC is the integrated SOC, SOC_M is the SOC of the main battery, MC_M is the maximum capacity of the main battery, SOC_A is the SOC for the auxiliary battery, and MC_A is the maximum capacity of the auxiliary battery.

7. The apparatus of claim 1, wherein:
the SOC of the main battery is a SOC for display in which an actual SOC range of the main battery, including a preset lower limit and a preset upper limit, is converted to correspond to a range of 0 to 100; and
the SOC for the auxiliary battery is a SOC for display in which an actual SOC range of the auxiliary battery, including a preset lower limit and a preset upper limit, is converted to correspond to a range of 0 to 100.

8. The apparatus of claim 1, wherein the program further includes instructions to display an output limit notification in response to the SOC of the main battery or the SOC for the auxiliary battery being less than a preset reference value.

9. The apparatus of claim 1, wherein the apparatus is configured to perform self-diagnosis based on an actual SOC of the main battery and an actual SOC for the auxiliary battery.

10. The apparatus of claim 1, wherein the program further includes instructions to calculate the integrated SOC in a state in which the vehicle is parked or stopped.

11. A vehicle comprising:
a main battery;
an auxiliary battery;
a charging and driving unit configured to charge the main battery with electric power stored in the auxiliary battery to maintain a state-of-charge (SOC) of the main battery at a minimum SOC or to drive a motor using the electric power stored in the main battery or the auxiliary battery; and
an apparatus configured to calculate an integrated SOC of the main battery and the auxiliary battery, based on the SOC of the main battery and a SOC for the auxiliary battery.

12. The vehicle of claim 11, wherein a maximum capacity of the auxiliary battery is lower than a maximum capacity of the main battery.

13. The vehicle of claim 11, wherein the auxiliary battery is a different type of battery from the main battery.

14. The vehicle of claim 11, wherein the apparatus is configured to calculate the integrated SOC of the main battery and the auxiliary battery in consideration of a maximum capacity of the main battery and a maximum capacity of the auxiliary battery.

15. The vehicle of claim 14, wherein the apparatus is configured to calculate the integrated SOC according to an equation,
ISOC=(SOC_M×MC_M+SOC_A×MC_A)/(MC_M+MC_A), wherein ISOC is the integrated SOC, SOC_M is the SOC of the main battery, MC_M is the maximum capacity of the main battery, SOC_A is the SOC for the auxiliary battery, and MC_A is the maximum capacity of the auxiliary battery.

16. The vehicle of claim 11, wherein:
the SOC of the main battery is a SOC for display in which an actual SOC range of the main battery, including a preset lower limit and a preset upper limit, is converted to correspond to a range of 0 to 100; and
the SOC for the auxiliary battery is a SOC for display in which an actual SOC range of the auxiliary battery, including a preset lower limit and a preset upper limit, is converted to correspond to a range of 0 to 100.

17. The vehicle of claim 11, wherein the apparatus is configured to display an output limit notification in response to the SOC of the main battery or the SOC for the auxiliary battery being less than a preset reference value.

18. The vehicle of claim 11, wherein the vehicle is configured to perform self-diagnosis based on an actual SOC of the main battery and an actual SOC for the auxiliary battery.

19. The vehicle of claim 11, wherein the apparatus is configured to calculate the integrated SOC in a state in which the vehicle is parked or stopped.

20. The vehicle of claim 11, wherein the charging and driving unit comprises:
a motor system comprising the motor and an inverter; and
an AC/DC converter configured to charge the main battery and the auxiliary battery with commercial electric power.
